(19) United States
(12) Patent Application Publication
(10) Pub. No.: US 2004/0027879 A1
(43) Pub. Date: Feb. 12, 2004

(54) Flash card reader

(76) Inventor: Cheng Chun Chang, Taipei (TW)

Correspondence Address: QUINTERO LAW OFFICE, 1617 BROADWAY, 3RD FLOOR, SANTA MONICA, CA, 90404, US

(21) Appl. No.: 10/628,975

(22) Filed: Jul. 28, 2003

(30) Foreign Application Priority Data
Aug. 12, 2002 (TW) 091212430

(51) Int. Cl. G11C 7/00

(52) U.S. Cl. 365/200

(57) ABSTRACT

A flash card reader having insertion slots in the face panel for receiving a flash memory card, a signal line with a USB connector for connection to the USB port of a computer, a controller for operation control, a hub chipset installed in the circuit board thereof and electrically connected to the signal line, the controller and USB jacks in the face panel, and a built-in data storage device electrically connected to the hub chipset.

### BACKGROUND OF THE INVENTION

1. Field of the Invention

The present invention relates to flash card readers, and more particularly, to such a flash card reader, which has at least one USB jack in the front face for receiving the USB plug of a peripheral apparatus. Therefore, in addition to the function of reading/writing a flash memory card, the flash card reader functions as an adapter between a computer and a peripheral apparatus.

2. Description of the Related Art

Using a flash card reader to read data from or write data into a flash memory card is a matured technique. For stable connection to a PC (personal computer) for rapid signal transmission, a flash card reader is provided with a signal line, which terminates in a USB connector for connection to the USB port of a computer. The USB port of a regular computer is located on a back board of the mainframe. When wishing to connect a peripheral apparatus, for example, a flash card reader or pen driver (or the so-called memory stick) to the USB port of a computer, the user may have to change the position of the computer or to move the computer to another place for the installation of the peripheral apparatus. There are computers that have the USB port provided at the front side for easy connection of a USB peripheral apparatus. However, when signal line of the USB peripheral apparatus may interfere with the in/out movement of the disk tray of the CD-ROM or a disk in the floppy disk-drive of the computer.

There is also known a USB junction box available on the market. The USB junction box has a USB signal line for connection to the USB port of a computer, and a plurality of USB jacks for receiving USB peripheral apparatus. When a flash card reader used with the USB junction box, much installation space is required.

Therefore, it is desirable to provide a flash card reader that eliminates the aforesaid problems.

### SUMMARY OF THE INVENTION

The present invention has been accomplished under the circumstances in view. According to one aspect of the present invention, the flash card reader comprises a face panel disposed in a front side thereof, at least one insertion slot disposed in the face panel for receiving a memory card, a signal line extended from a rear side thereof and terminating in a USB connector for connection to the USB port of a computer, a circuit board, and a controller electrically connected to the circuit board thereof for operation control; wherein the circuit board comprises a hub chipset electrically connected to the signal line, the controller and at least one USB jack being respectively installed in the face panel; the controller is electrically connected to the at least one insertion slot.

According to another aspect of the present invention, the flash card reader further comprises a built-in data storage device, the built-in data storage device comprising a pen driver chipset electrically connected to the hub chipset, and a compact flash memory controlled by the pen driver chipset.

### BRIEF DESCRIPTION OF THE DRAWINGS

FIG. 1 is an elevational view of a flash card reader according to the present invention.

FIG. 2 is a circuit block diagram of the present invention.

### DETAILED DESCRIPTION OF THE PREFERRED EMBODIMENT

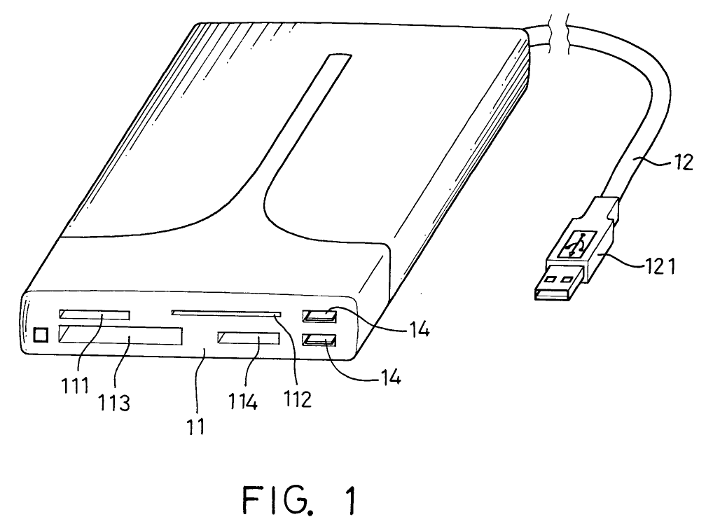

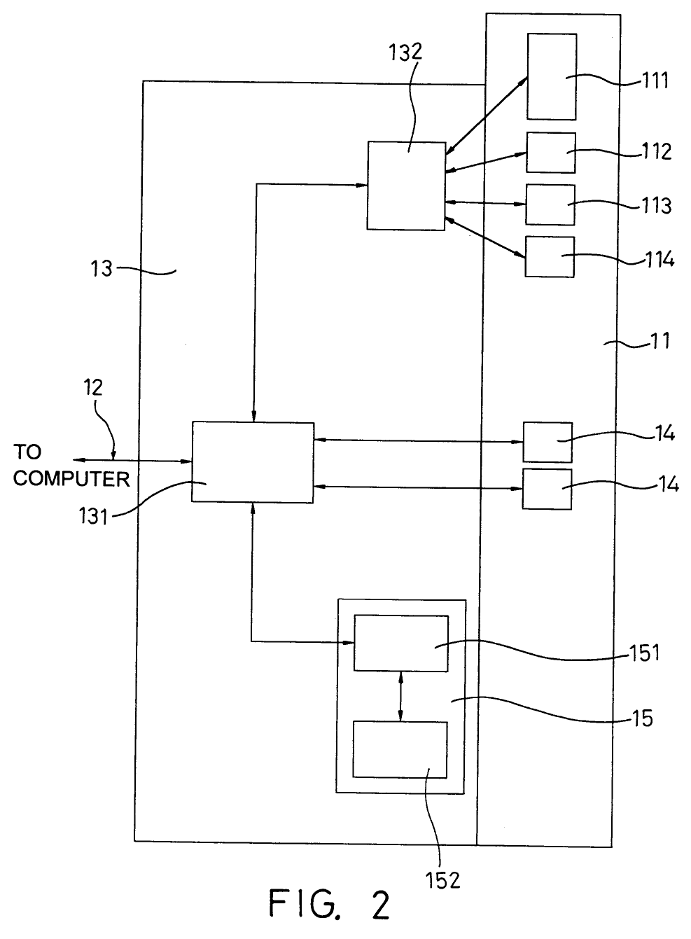

Referring to FIGS. 1 and 2, a flash card reader 1 is shown comprising a front face panel 11. The face panel 11 has at least one insertion slot for the insertion of a memory card, for example, a SM card (Smart Media Card). According to the present preferred embodiment, the face panel 11 has four insertion slots 111˜114 for the insertion of MMC card, SD card, MS card, CF card (Type I and Type II). This four-slot design is not a limitation. The face panel 11 can also be made to have two or three insertion slots. The card reader 1 further comprises a signal line 12 extended from the other side (opposite to the face panel 11). The signal line 12 has a USB interface connector 121 for connection of a USB port of a computer for transmission of signal.

The internal circuit board, referenced by 13, of the card reader 1 comprises a hub chipset 131. The hub chipset 131 has one end electrically connected to the signal line 12 and the other end electrically connected to a controller 132 through multiple signal pins. The controller 132 is electrically connected to the insertion slots 111˜114. Through the signal line 12, the hub chipset 131, and the controller 132, the computer can read and write a memory card inserted in one of the insertion slots 111˜114. Further, the hub chipset 131 is electrically connected to at least one, for sample, two USB jacks 14 in the face panel 11 for receiving the USB plug of any of a variety of peripheral apparatus, for example, a joystick or pen driver.

In order to enhance the storage function of the card reader 1, a storage device 15 is provided at the circuit board 13. The storage device 15 comprises a pen driver chipset 151 electrically connected to the hub chipset 131, and a compact flash memory 152 controlled by the pen driver chipset 151. The memory capacity of the compact flash memory 152 can be 32MB, 64MB, or 1GB. Subject to the aforesaid design, the card reader 1 functions as a mobile data storage device.

As indicated above, the card reader of the present invention uses a signal line for connection to the USB port of a computer, a hub chipset installed in the circuit board thereof and electrically coupled to the controller and at least one USB jack in the face panel thereof, for reading/writing a flash memory and controlling the operation of peripheral apparatus. Further, a built-in storage device expands the memory capacity of the linked computer.

A prototype of card reader has been constructed with the features of FIGS. 1 and 2. The card reader functions smoothly to provide all of the features discussed earlier.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A flash card reader comprising a face panel disposed in a front side thereof, at least one insertion slot disposed in said face panel, a signal line extended from a rear side thereof and terminating in a USB connector for connection to the USB port of a computer, a computer, a circuit board, and a controller electrically connected to said circuit board thereof for operation control, characterized in that: the circuit board of the flash card reader comprises a hub chipset respectively coupled to said signal line, said controller and at least one USB jack, wherein said controller is coupled to said at least one insertion slot, for enabling the flash card reader to have the read/write function to a flash memory card and the function of connecting computer peripheral apparatus.

2. The flash card reader as claimed in claim 1, wherein said at least one insertion slot includes a plurality of insertion slots for receiving different memory cards.

3. The flash card reader as claimed in claim 1, wherein the number of said at least one USB jack is 2.

4. The flash card reader as claimed in claim 1, further comprising a built-in data storage device, said built-in data storage device comprising a pen driver chipset electrically connected to said hub chipset, and a compact flash memory controlled by said pen driver chipset.
